(19) United States
(12) Patent Application Publication
(10) Pub. No.: US 2012/0287263 A1
(43) Pub. Date: Nov. 15, 2012

(54) INFRARED INSPECTION OF BONDED SUBSTRATES

(75) Inventor: Wei Zhou, Minnetonka, MN (US)

(73) Assignee: Rudolph Technologies, Inc., Flanders, NJ (US)

(21) Appl. No.: 13/510,135

(22) PCT Filed: Nov. 16, 2010
(86) PCT No.: PCT/US2010/056785

§ 371 Date: Jul. 30, 2012

Related U.S. Application Data
(60) Provisional application No. 61/261,737, filed on Nov. 16, 2009.

(51) Int. Cl. H04N 7/18; H01L 29/26

(52) U.S. Cl. 348/126; 257/798; 257/E29.079; 348/E05.075

(57) ABSTRACT

A method and apparatus for obtaining inspection information is described. A standard CCD or CMOS camera is used to obtain images in the near infrared region. Background and noise components of the obtained image are removed and the signal to noise ratio is increased to provide information that is suitable for use in inspection.

### CROSS-REFERENCE TO RELATED APPLICATIONS

This application is a national stage of PCT Application Serial No. PCT/US10/56785, filed Nov. 16, 2010, which claims priority to U.S. Provisional Ser. No. 61/261,737, filed Nov. 16, 2009; the entire teachings of which are incorporated herein by reference.

### TECHNICAL FIELD OF THE INVENTION

The present invention relates generally to the inspection of substrates and in particular to the inspection of semiconductor substrates using infrared radiation.

### BACKGROUND OF THE INVENTION

In order to increase the power of semiconductor devices it is necessary to increase the density of structures in such a device. Historically this has been done by shrinking the size of the devices themselves such that more power may be built into a given space. Another means for accomplishing an increase in density involves connecting multiple such devices to one another, as in a computer that connects multiple processors together to perform parallel processing operations. In other instances, this is done by forming multiple separate semiconductor devices that are packaged together as a single device. One example of this type of structure is a multi-core processor of the type available from Intel or Advanced Micro Devices. A proposed method for further increasing the density of semiconductor devices involves stacking such devices, the one on top of the other.

Stacking semiconductor devices presents unique challenges for fabrication as it is difficult to ensure that stacking is done accurately and precisely. Electrical connectors such as bond pads, solder or gold bumps, vias and the like used to electrically connect stacked semiconductor devices to one another and to the package in which the stacked devices are housed are quite small and any deviation is problematic. Further, because large portions of semiconductor devices are covered with structures that are opaque or are formed on substrates that are opaque, it is difficult to utilize traditional optical inspection and metrology systems to ensure that the semiconductor devices are aligned.

In addition to ensuring the proper alignment of stacked semiconductor devices, it is difficult to ensure that the adhesives used to bond stacked devices to one another are properly applied and cured. Voids, cracks, debris and other problems may render the stacked semiconductor devices inoperable or unreasonably likely to fail. But again, it is difficult to perform inspection or metrology of the adhesive layer as it is located between substrates that may themselves be at least partially opaque and which may have structures formed thereon that are opaque.

One possible solution to the problem of ensuring alignment and the proper adhesion of the stacked devices is to utilize infrared illumination and sensors to perform inspection and metrology operations on the stacked devices. However, there are problems associated with traditional infrared sensors that make them less than optimal solutions for inspection and/or metrology. Among these problems is the fact that infrared sensors and cameras are made using processes that are quite expensive and accordingly, there is a large cost differential between standard CCD and CMOS cameras and an infrared camera. Standard infrared sensors are also, as one may presume, selectively insensitive to visible wavelengths of light and accordingly have reduced utility for standard 2D and 3D inspection applications.

Further, infrared cameras at present are not able to achieve the same level of resolution as do standard CCD and CMOS cameras. This results in a situation where higher resolution optics are required, which in turn results in a much smaller field of view for the optical system. As is readily understood by those skilled in the art, a smaller field of view results in a much slower throughput for an inspection system.

Accordingly, what is needed is an imaging system sensitive to infrared radiation and capable of performing required alignment and process excursion inspection at a rate and resolution that meets the needs of today's cost conscious semiconductor fabricators.

### BRIEF DESCRIPTION OF THE DRAWINGS

FIG. 1 is a schematic illustration of one embodiment of an optical system for the inspection of substrates.

FIG. 2 illustrates schematically an exploded view of substrates that are to be stacked.

FIG. 3 illustrates schematically a stacked substrate.

FIG. 4 is a graph of light intensity per pixel.

FIG. 5 is a flow chart illustrating steps of one embodiment of the present invention.

FIG. 6 is a flow chart illustrating steps of one embodiment of the present invention.

### DETAILED DESCRIPTION

In the following detailed description of the invention, reference is made to the accompanying drawings that form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

The present invention involves using the generally neglected near infrared sensitivity of standard CCD and/or CMOS cameras to capture images of stacked or laminated substrates S that are useful for inspection of those substrates S. The output of the inspection system 10 may be used for ensuring proper alignment between layers of a stacked or laminated substrate S, and for locating and/or identifying process variation and/or excursions such as improper bonding of layers, voids, cracks, debris and other problems that occur in the process of stacking layers to form a substrate S. Data resulting from such inspections may be used to directly or indirectly control or modify device fabrication tools and processes such that subsequent substrates and the devices that are obtained therefrom are different from the ones initially inspected.

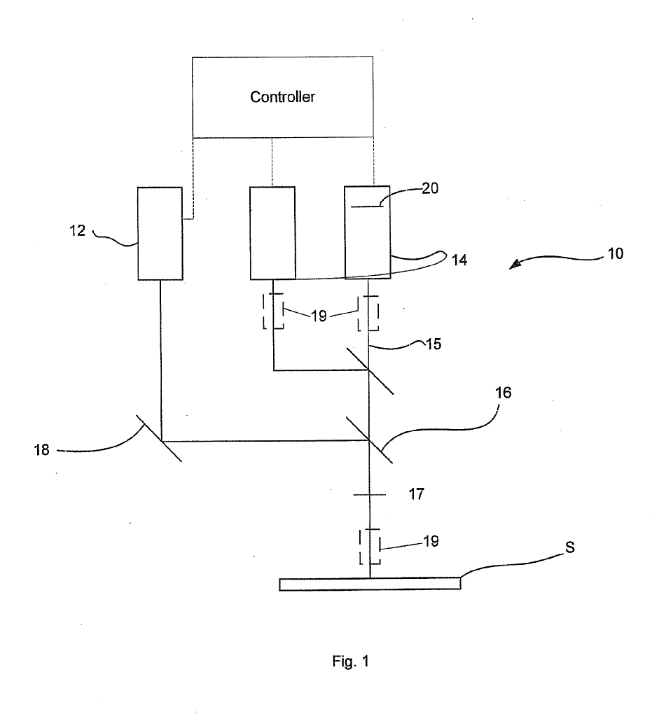

FIG. 1 illustrates one embodiment of an inspection system 10 that may be used to inspect a substrate 10 supported on a stage (not shown) arranged to move the substrate S in three dimensions (X, Y, Z) and to rotate the substrate S about the vertical axis Z to facilitate the capture of images by inspection system 10. Inspection system 10 at a minimum includes an illuminator 12 adapted to direct electromagnetic radiation at a given wavelength, at selected wavelengths, or at desired ranges of wavelengths and a camera 14 which is adapted to capture images of the substrate S using at least a portion of the radiation provided by the illuminator 12. In the embodiment illustrated, the illuminator 12 is coupled into an optical path 15 that extends from the camera 14 to the substrate by means of a beam splitter 16. The illuminator 12 may be directed through flexible optical fiber type conveyances to beam splitter 16 or may be directed through the air by means of turning mirrorS18 or the like to the beam splitter 16. Radiation from illuminator 12 is directed downward onto the sample S in a normal orientation, though it is contemplated that oblique angles of incidence may be utilized and that any modifications to the inspection system 10 required to enable oblique angles of incidence are within the ken of those skilled in the art.

Radiation is returned from the substrate S through beam splitter 16 and optional beam splitter 16′ to camera 14 where it is incident upon sensor 20. Other optomechanical devices such as optical fiber mixing or switching devices may also be used to optically connect an illuminator 12 to system 10. It is preferred to utilize readily available CCD or CMOS sensors in the camera 14. While CCD and CMOS sensors 20 are generally considered more useful for imaging in the visible wavelengths (approximately in the range of about 380 nm to about 1000 nm). It has been found that some CCD and CMOS sensors 20 have sensitivity to wavelength of light in the range of about 1000 nm to about 1300 nm, though this sensitivity falls off relatively quickly at the longer wavelengths. Using this sensitivity one is able to perform fast, high resolution inspection of substrates S using infrared radiation in the range of wavelengths from about 1 micron to about 1.3 microns (1000 nm-1300 nm). BlockS19 in FIG. 1 generically represent optical elements such as lenses used to focus, collimate, and/or otherwise condition or shape the radiation incident upon the substrate S and returned to the camera 14.

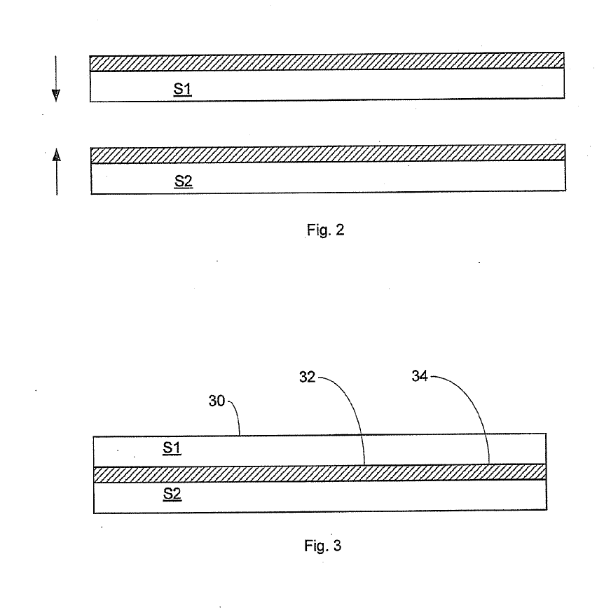

FIGS. 2-3 illustrate schematically various types of stacked substrates S. While substrates S described in this application relate to substrates used to form semiconductor devices, other types of stacked or laminated substrates may be addressed using the present invention. Stacked integrated circuit devices may be formed from one or more individual integrated circuit devices that are, as one would guess, stacked, the one on the other. This is generally achieved by stacking entire wafers on which integrated circuit devices are formed rather than by stacking individual integrated circuit devices (“IC's”), though it is also possible to form a stacked substrate S in this manner on an individual device basis. FIG. 2 illustrates a pair of substrates, S1 and S2 in the act of being stacked, the one on the other, with the backside of substrate S1 being placed in contact with the upper surface substrate S2. A suitable glue or adhesive is used to secure the wafers together. As suggested above, two, three, four or more substrates or IC's can be stacked. Note that while a back to front stacking is shown in FIG. 2, a face to face arrangement such as that shown in FIG. 3 or a back to back arrangement (not shown) is also possible, provided that appropriate electrical connections and packaging are allowed for.

As will be appreciated, it can be difficult to inspect the bond between the substrates S1 and S2 shown in FIGS. 2 and 3. However, because the camera sensor 20 is sensitive to wavelengths of infrared light to which silicon is more or less transparent, the bond between the substrates S1 and S2 can be optically inspected. Using the inspection system 10, radiation including infrared radiation to which the camera 14 is sensitive, is incident upon the substrate S. A filter (not shown) is emplaced between illuminator 12 and beam splitter 16 or between substrate S and camera 14 to remove all radiation to which the substrate S is not at least partially transparent. This filter is preferably selectable and can be emplaced or removed to filter out radiation to which the substrate S is not at least partially transparent or to allow the use of broadband or selected radiations of other wavelengths. In some embodiments therefore, when stacked or laminated substrates S are to be inspected, radiation having a wavelength between about 1.0 microns and 1.3 microns may be used.

The radiation incident upon the substrate S is returned to the camera 14 where it is incident upon the sensor 20 so as to form an image. This image is passed to the controller, which is provided with the requisite computer hardware and software for collecting and processing such images to provide useful output and/or to directly or indirectly control aspects of the fabrication of the substrates S and the IC's that are formed thereon.

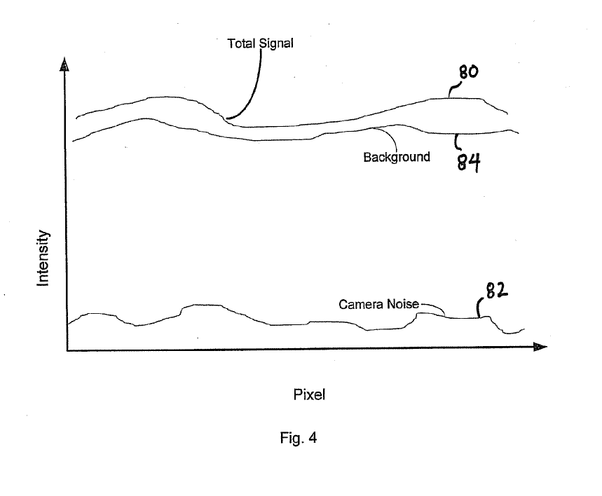

FIG. 4 illustrates schematically the intensity of the light sensed by the sensor 20 on a pixel by pixel basis. Note that FIG. 4 is illustrative only and may not represent actual data. In one embodiment, the sensor 20 is capable of providing greyscale output of between 0 and 255. In other embodiments, the sensor 20 is capable of providing color image information in RGB or any other suitable color scheme. For simplicity's sake, the invention will be described in an embodiment where each pixel of the image that represents the substrate S has a greyscale intensity value of between 0 and 255.

The top line 80 in the graph of FIG. 4 represents the total intensity of each of the pixels. This intensity value has a number of components, only some of which will be described here in detail. The lowest line in the graph represents noise introduced into the pixel values by the sensor 20 itself. This noise tends to be random in nature, but its magnitude tends to predictable within margins. The space between the bottom line 82 and the middle line 84 on the graph represents the total intensity of each pixel that results from undesirable scattering within the substrate S itself and from reflection from the top surface 30 of the substrate (closest to the camera 14) and the bottom surface 32 of the substrate. Note that in a stacked or laminated substrate S, it is often desirable to focus inspection on the region or volume between the stacked substrates S1 and S2. This volume 34 may contain structures such as circuitry or vias or simply the adhesive used to bond the substrates together. When using wavelengths of radiation between about 1.0 and 1.3 microns a significant portion of the light will be reflected back to the sensor 20 from the upper and lower surfaces 30, 32 of the substrate S1. Further, a portion of the incident light will be scattered within the substrate S1 and some of the scattered light will make it back to the sensor 20. The area of the graph between the top line 80 and the middle line 84 represents that portion of the incident radiation that is reflected or scattered from structures, adhesives or the like in the volume 34 under inspection. This portion of the total signal is of interest for the purposes of inspection as its characteristics are derived from the structures of interest.

The difficulty in using standard CCD and CMOS cameras at near IR wavelengths is that the portion of the total signal that is of interest is small compared to the background portion of the signal and is often comparable to the amount of noise introduced by the sensor 20 itself. Accordingly, it is necessary to remove the background portion of the total signal and to improve the signal to noise ratio of the remaining image.

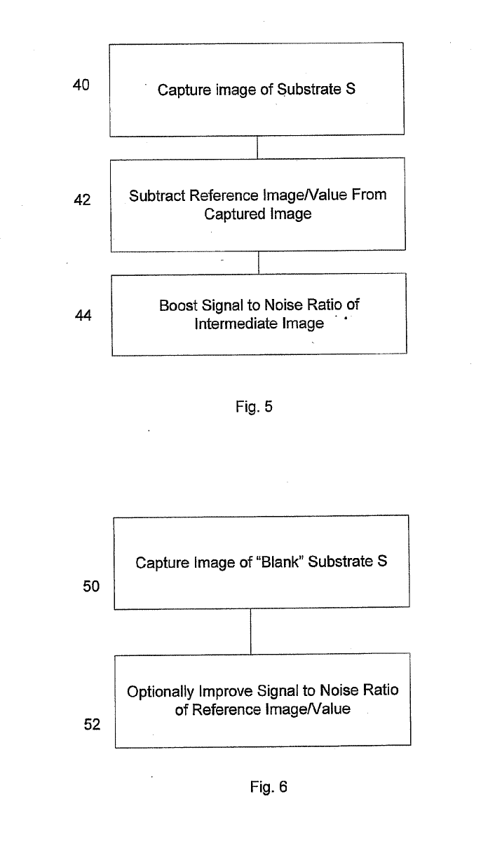

FIG. 5 is a flow chart of the basic approach of one embodiment of the present invention. At step 40, the substrate S is illuminated and an image is captured. At step 42, a reference image or value is subtracted from the image captured at step 40 to form an intermediate image. This can be done mathematically or optically as will be described hereinbelow. At step 44, the signal to noise ratio of the intermediate image is boosted to form a final image that can be used for inspection of the volume or region 34 of the substrate S. Note that in one embodiment, some or all of step 40 may be carried out by means of software operating on the controller which is connected to inspection system 10.

Typically all of step 44 will be carried out on the controller, though in some embodiments the camera 14 may be provided with some of the capabilities (hardware and/or software) required to boost the signal to noise ratio.

In one embodiment, the preparation of a reference image/value is carried out as shown in FIG. 6. In step 50, the stage on which substrate S rests is driven such that a field of view of the camera 14 addresses a “blank” spot of the substrate S. A blank spot is characterized by a relative lack of structure within the volume 34 between the individual layers S1 and S2 of the substrate S. In this instance, the amount of light reflected or scattered from structures in volume 34 is minimal or even substantially zero and accordingly the combined magnitude of the background and noise signals may be known. As an optional step 52, one may capture multiple images of one or more “blank” spots and sum the pixel values of each of these images. As the noise present in each of these images tends to be vary above and below a given magnitude, the portion of the summed pixel value that is related to noise increases slowly whereas the consistently positive summed pixel values of the background grows linearly, thereby increasing the signal to noise ratio. Note that the summed values must be normalized with the image of the substrate S that is obtained for inspection purposes to avoid mismatched image and reference values. In one embodiment, the “blank” spot may actually be several suitable sites on a substrate S that is under inspection, each of the images obtained from the blank spots being summed as described above to create a reference image/value. These blank spots may be manually selected by a user working through a user interface of the inspection system 10 or may be automatically selected by the inspection 10 based on criteria entered by the user. As the substrates S may differ from one another in size, shape, i.e. type, material and the like, the criteria for what constitutes a blank spot suitable for the formation of a reference image/value are variable as well. At a very basic level, because the output of the inspection system may vary based on preference and circumstances, what constitutes a suitable blank spot for purposes of creating a reference image/value is one that a user of the system determines provides a suitable result. A more objective approach may include selecting a number of candidate areas or blank spots which are imaged and used to generate an inspection result. A suitable figure of merit may be selected to optimize or score the use of selected ones or a set of selected ones of the blank spots as a reference image or to create a reference value or model.

In another embodiment, rather than using the substrate S that is under test, a separate unstacked or unlaminated substrate S may be used to capture images for the creation of reference image/value. For example, in lieu of a stacked substrate S, a single thickness silicon wafer may be used so long as the wafer has an upper surface, lower surface, thickness and optical characteristics similar to those of the upper layer Si of a stacked or laminated substrate S.

Where the process described in conjunction with FIG. 6 is used, an image subtraction process may be used wherein the pixel values of the reference image are directly subtracted from the corresponding pixel values of the inspection image. This may take place mathematically in the controller or logically (or mathematically) in the camera 14. The resulting intermediate image should have a much improved signal to noise ration with respect to the structures that are under inspection in the volume 34.

As an intermediate step, it is often desirable to provide output to a user of the inspection system 10. It is often the case, however, that the intermediate images will have to be gamma corrected for user review. This process is fairly well understood, however it should be understood that a user may elect to have the intermediate images gamma corrected only for output or review purposes, or the intermediate images may be further processed in their gamma corrected state. This step is optional.

In either case, it is desirable to improve the signal to noise ratio of the intermediate images to produce final images of better quality. Note that the intermediate images, taken together, will encompass substantially all of the substrate S that is to be inspected. Accordingly, each of the intermediate images is addressed to improve the signal to noise ratio. In one embodiment that is similar to step 52 described above, multiple intermediate images are captured and summed to increase the portion of the image that results from actual structure as opposed to that due to noise. In one instances, an area scan camera 14 is used with a strobing illuminator 12 to rapidly obtain multiple inspection images, each of which is modified as described in step 42 above by the application of the reference image/value. Subsequently, the multiple corresponding images are summed or otherwise combined to increase the signal to noise ratio of the resulting final image. Note that the final image pixel values are normalized with respect to the intermediate images and the reference image/value to ensure proper image processing.

In another embodiment, a continuous scan inspection system 10 has a continuous illumination illuminator 12 that operates in conjunction with a camera 14 that utilizes a mechanical or electronic shutter to freeze motion of the continuously moving substrate S. As above, multiple passes of the inspection system 10 may obtain the requisite number of inspection images that are subsequently processed by application of the reference image/value. In yet another embodiment, a single pass of the inspection system 10 is made (using either strobe or continuous illumination) while the camera 14 oversamples the substrate 14 and uses the multiple, oversampled images to obtain the requisite inspection images. In another embodiment of the present invention, an area scan camera 14 is used in a mode similar to that of a TDI linescan camera to oversample the substrate S. In another embodiment, one or more TDI or linescan cameraS14 are used to capture inspection images of the substrate S either in multiple passes (as where a single camera 14 is used) or in a single pass (as where multiple cameraS14 are used). Note that in any of the embodiments described above, processing of inspection images into intermediate images and processing of intermediate images into final images may take place on a continuous basis as information is collected or it may be carried out by the controller only after the actual inspection (imaging) has been completed. Further processing may be carried out by a controller that is local to the inspection system 10 or by a controller that is partly or wholly distributed outside of the inspection system 10.

In another embodiment of the invention, frequency domain filtering is used in lieu of the subtraction of a reference image/value to create the intermediate image.

Frequency domain filtering may take place mathematically by performing a Fourier Transform on the reference image of the blank space to obtain a mathematical value for the background signal. Frequency domain filtering may also take place by optical means wherein a pupil or mask of a suitable shape and size which is determined by means of Fourier Transform analysis is placed in the back focal plane 17 of the inspection system.

The mask or pupil at the back focal plane 17 simply blocks those rays that contribute to the background signal from ever reaching the sensor 20 of the camera. Note that as the sensor's 20 performance changes over time or as the nature of the substrate S changes, it may be necessary to modify the pupil or mask at the back focal plane. This may be accomplished by forming the mask on a transparent slide that may be readily removed and replaced.

Alternatively, it may be possible to place an electrophoretic display at the back focal plane.

An electrophoretic display is a transparent plate that includes electrically controllable pixels that can be made to become opaque. This phenomenon is often referred to as electronic ink. In any case, an electrophoretic display could be modified on the fly to accommodate required changes in the mask.

In addition to increasing the signal to noise ratio, a blurring process step may optionally be taken to further remove random, single pixel noise from the inspection images, the reference image/value, and/or the intermediate or final images, as needed.

### CONCLUSION

Although specific embodiments of the present invention have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A method of capturing inspection data from a silicon substrate comprising:
illuminating a substrate having a top surface and a bottom surface with radiation to which the substrate is at least partially transparent;
sensing illumination radiation to which the substrate is at least partially transparent with a sensor to form an image, at least a portion of the image being comprised of radiation returned from at least one of the upper surface and the bottom surface of the substrate and at least another portion of the image being comprised of radiation returned from a structure located at or beyond the bottom surface of the substrate with respect to the sensor;
subtracting from the image an image reference representative of radiation returned from at least one of the upper and lower surfaces of the substrate to form an intermediate image;
and, summing multiple intermediate images to create a final image of the silicon substrate suitable for inspection.

2. The method of capturing inspection data from a silicon substrate of claim 1 wherein the sensor is one of a CCD and a CMOS camera.

3. The method of capturing inspection data from a silicon substrate of claim 1 wherein the radiation to which the substrate is at least partially transparent has a wavelength of approximately 1 micron to 1.3 microns.

4. The method of capturing inspection data from a silicon substrate of claim 1 further comprising selectively using the sensor to perform an inspection of a silicon substrate using visible wavelengths.

5. The method of capturing inspection data from a silicon substrate of claim 1 wherein the illuminator is provided with a filter that omits radiation having wavelengths less than about 1 micron.

6. The method of capturing inspection data from a silicon substrate of claim 5 wherein the filter in the illuminator may be employed to selectively allow broadband or filtered The method of capturing inspection data from a silicon substrate of claim 1 wherein the image reference is formed by capturing at least one image of a reference location of the silicon substrate.

7. The method of capturing inspection data from a silicon substrate of claim 6 wherein the image reference is formed by capturing at least one image of a reference location of the silicon substrate having no structure located at or beyond the bottom surface of the substrate with respect to the sensor.

8. The method of capturing inspection data from a silicon substrate of claim 6 wherein the image reference is formed by capturing at least one image of a reference substrate formed of a substance that is optically similar to the silicon substrate, the reference substrate having an upper and a lower surface and no structure located at or beyond the bottom surface of the substrate with respect to the sensor.

9. The method of capturing inspection data from a silicon substrate of claim 1 wherein an intermediate image is gamma corrected.

10. The method of capturing inspection data from a silicon substrate of claim 9 wherein each intermediate image is gamma corrected before being summed.

11. The method of capturing inspection data from a silicon substrate of claim 1 wherein the final image is gamma corrected.

12. The method of capturing inspection data from a silicon substrate of claim 1 wherein the final image is blurred to remove individual pixel noise.

13. The method of capturing inspection data from a silicon substrate of claim 1 wherein the image reference is a frequency domain filter obtained from a Fourier transform of the image sensed by the sensor.

14. The method of capturing inspection data from a silicon substrate of claim 1 wherein the frequency domain filter comprises a physical mask placed at the back focal plane of the optical system.

15. The method of capturing inspection data from a silicon substrate of claim 1 wherein the frequency domain filter is applied mathematically to the image sensed by the sensor on a pixel by pixel basis.

16. The method of capturing inspection data from a silicon substrate of claim 1 wherein the inspection data is used to identify defects in the silicon substrate.

17. The method of capturing inspection data from a silicon substrate of claim 1 wherein the defects in the silicon substrate are selected from a group consisting of chips, cracks, voids, particles, and dimensional deviation.

18. The method of capturing inspection data from a silicon substrate of claim 1 wherein the inspection data is used to identify process excursions, quantify process excursions and to modify process variables to modify subsequently processed silicon substrates.

19. A semiconductor device formed from a silicon substrate formed according to claim 18.

20. An imaging system for capturing inspection data comprising:
a camera having a sensor sensitive to radiation in the visible wavelengths and infrared wavelengths of approximately 1 micron to 1.3 microns;
an illuminator for directing radiation to which the camera sensor is sensitive onto a substrate having an upper surface, a lower surface, at least one area with a structure of interest formed at or below the lower surface of the substrate relative to the position of the camera, at least a portion of the radiation from the illuminator being returned from the upper surface of the substrate to the camera, at least another portion of the radiation from the illuminator being returned from the lower surface of the substrate.
